(19) United States
(12) Patent Application Publication
(10) Pub. No.: US 2009/0244877 A1
(43) Pub. Date: Oct. 1, 2009

(54) PCB layout structrue for suppressing EMI and method thereof

(76) Inventors: Wei-Hao Yeh, Taichung city (TW); Ying-Fu Hung, Douliou city (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/078,485

(22) Filed: Apr. 1, 2008

(51) Int. Cl. H05K 9/00

(52) U.S. Cl. 361/818

(57) ABSTRACT

A PCB layout structure for suppressing EMI and a method thereof is disclosed. The PCB layout structure for suppressing EMI includes a multi-layer PCB, a plurality of electric grids, and a plurality of conductive vias. The multi-layer PCB has a plurality of signal layers and a grounding layer. Each of the signal layers is disposed with a plurality of signal lines. The plurality of electric grids are disposed on each of the signal layers and cover the signal lines on each of the signal layers. The plurality of conductive vias are located between the layers of the multi-layer PCB to electrically connect the grounding layer with the electric grids on each of the signal layers. Thereby, electromagnetic waves of a specific wavelength are shielded by appropriately choosing the dimensions of the electric grids.

### BACKGROUND OF THE INVENTION

1. Field of the Invention

The present invention relates to a PCB layout structure for suppressing EMI and a method thereof. In particular, this invention relates to a PCB layout structure and a method thereof that has high frequency signals and can suppress EMI.

2. Description of the Related Art

All electronic devices with high frequency signals will generate noise. Electronic noise can be divided into conducting interference and radiating interference. Generally, conducting interference is transmitted by the power wire and interferes with other electronic devices, and radiating interference is transmitted by radiation and interferes with other equipment. Therefore, the national electric equipment safety specification has a rule for regulating the EMI.

As the technology has been developed, electromagnetic interference (EMI) becomes a key issue. When the speed of a semiconductor becomes faster and its density becomes heavy, noise also becomes bigger. For a PCB layout engineer, EMI becomes a serious problem. By using a proper PCB layout technology and a systematic design method, the EMI problem can be overcome.

Currently, a sheltering method is the most popular method to reduce EMI or suppressing EMI. For example, the cable is wrapped with a layer of sheltering screen which grounded, or a metal conducting element is placed around the elements in the housing of the electronic device that emit the electromagnetic wave. Theses methods increase the manufacturing cost of the electronic device, and the electronic device becomes complex.

### SUMMARY OF THE INVENTION

One particular aspect of the present invention is to provide a PCB layout structure for suppressing EMI and a method thereof that dispose a plurality of electric grids on the signal layer of the PCB to cover the signal lines on the signal layer. The electronic-conducting grids destroy the interference magnetic filed generated by the signal lines so that the area of the magnetic field on the PCB is reduced and the noise radiation is weaken. Thereby, the EMI is suppressed.

The PCB layout structure for suppressing EMI includes a multi-layer PCB, a plurality of electric grids, and a plurality of conductive vias. The multi-layer PCB has a plurality of signal layers and a grounding layer. Each of the signal layers is disposed with a plurality of signal lines. The plurality of electric grids are disposed on each of the signal layers and cover the signal lines on each of the signal layers. The plurality of conductive vias are located on each layer of the multi-layer PCB to electrically connect the grounding layer with the electric grids on each of the signal layers. Thereby, specific electromagnetic waves are shielded by appropriately choosing the dimensions of the electric grids.

The PCB layout method for suppressing EMI is implemented on a multi-layer PCB. The multi-layer PCB has a plurality of signal layers and a grounding layer. The method includes the following steps. Firstly, a plurality of electric grids are formed on each of the signal layers of the PCB, and the electric grids cover the signal lines on each of the signal layers. The size of electric grid depends on the frequency of the electromagnetic waves desired to be shielded. Next, a plurality of conductive vias are formed between the layers of the multi-layer PCB. The conductive vias electrically connect the grounding layer with the electric grids on each of the signal layers to form an enclosed grounding net. Thereby, specific electromagnetic waves are shielded by appropriately choosing the dimensions of the electric grids.

The PCB layout structure for suppressing EMI and a method thereof of the present invention use the electric grid layout to shield electromagnetic waves with a specific frequency. The layout structure and the method thereof of the present invention can reduce the area distributed by the interference magnetic field to weaken the noise radiation to suppress the interference between signals. Furthermore, the density of the conductive vias can be reduced 30˜50% so that the strength of the PCB will not become weak. Moreover, by using the electric grid layout method of the present invention, the electroplate cost is reduced about 25˜30%.

For further understanding of the invention, reference is made to the following detailed description illustrating the embodiments and examples of the invention. The description is only for illustrating the invention and is not intended to limit of the scope of the claim.

### BRIEF DESCRIPTION OF THE DRAWINGS

The drawings included herein provide a further understanding of the invention. A brief introduction of the drawings is as follows:

FIG. 1 is a schematic diagram of the PCB layout structure of the present invention;

FIG. 2 is a schematic diagram of the surface layer of the PCB of the present invention;

FIG. 3 is a schematic diagram of the electric grids of the present invention; and

FIG. 4 is a flow chart of the PCB layout method for suppressing EMI of the present invention.

### DETAILED DESCRIPTION OF THE PREFERRED EMBODIMENTS

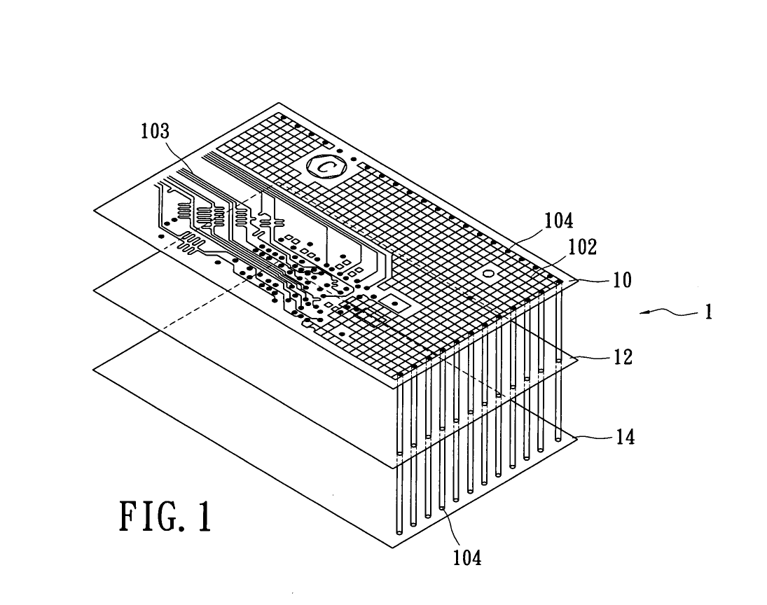

Reference is made to FIG. 1, which shows a schematic diagram of the PCB layout structure of the present invention. The PCB layout structure for suppressing EMI includes a multi-layer PCB 1, a plurality of electric grids 102, and a plurality of conductive vias 104. The multi-layer PCB 1 has a first signal layer 10, a second signal layer 14, and a grounding layer 12. The first signal layer 10 and the second signal layer 14 are disposed with a plurality of signal lines 103 and the plurality of electric grids 102. The electric grids 102 are used for covering the signal lines 103. The conductive vias 104 electrically connect the grounding layer 12 with the electric grids 102 on the first signal layer 10 and the second signal layer 14.

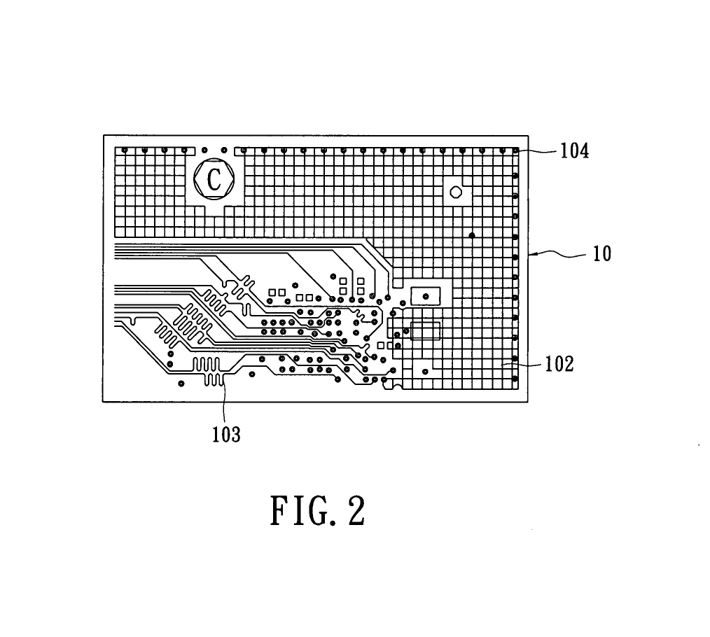

Reference is made to FIGS. 1 and 2. FIG. 2 shows a schematic diagram of the surface layer of the PCB of the present invention. A plurality of signal lines 103 are disposed on the first signal layer 10, and the signal lines 103 generate electromagnetic noise when being operated at high frequency. The electromagnetic noise is conducted or radiated to interfere the other electronic elements on the first signal layer 10 via the power wire and air. Therefore, the first signal layer 10 is disposed with the electric grids 102, and the electric grids 102 cover the signal lines 103 to shield the electromagnetic noise interference.

Reference is made to FIGS. 1 and 2 again. The first signal layer 10 also is disposed with a plurality of conductive vias 104. The conductive vias 104 is electrically connected with the electric grids 102 on the first signal layer 10. The conductive vias 104 are disposed around the multi-layer PCB, whereby the distance between them is two times the length of grid cell. Moreover, the conductive vias 104 are electrically connected with the electric grids (not labeled) on the second signal layer 14 and the grounding layer 12 of the multi-layer PCB 1. Therefore, the electric grids on the first signal layer 10 and the second signal layer 14 of the multi-layer PCB 1 are electrically connected with the grounding layer 12 via the conductive vias 104 to form an enclosed grounding net.

Reference is made to FIGS. 1 and 2 again. When the signal lines 103 are operated at high frequency and generate electromagnetic noise, the electromagnetic noise is guided to the grounding layer 12 to release by connecting the signal lines 103 with the electric grids of the grounding layer 12 via the conductive vias 104. Thereby, the distribution of the magnetic force lines of the electromagnetic noise is destroyed to reduce the distribution area of the magnetic field and the electromagnetic noise radiation is weakened.

Therefore, the first signal layer 10 and the second signal layer 14 of the multi-layer PCB 1 are disposed with the large area electric grids 102. The large area electric grids 102 fully cover the signal lines 103 of the first signal layer 10 and the second signal layer 14 to shield the electromagnetic noise generated from the signal lines 103. Thereby, the EMI suppressing effect is achieved.

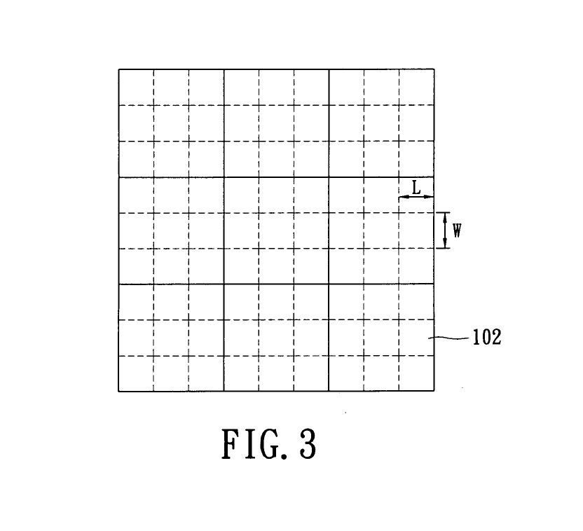

Reference is made to FIG. 3, which shows a schematic diagram of the electric grids of the present invention. The electric grid 102 is a grid cell. The length L of the grid cell is equal to the width W. The dimension of the grid cell is obtained by formula (1).

C=f×λ (1)

In formula (1), C is the velocity of light. f is the frequency of the electromagnetic waves to be shielded. λ is the wavelength of the electromagnetic waves to be shielded. Because the velocity of light C is a constant, the frequency f of the electromagnetic waves to be shielded and their wavelength λ are inversely proportional.

For determining the dimension of grid cell, firstly the frequency f of the electromagnetic waves to be shielded is determined. Next, according to formula (1), the wavelength λ of the electromagnetic waves to be shielded is obtained. The length of grid cell is equal to the wavelength λ of the electromagnetic waves to be shielded divided by n (n is an integer). The length L and the width W of grid cell is calculated by formulas (2) and (3). n is an integer.

L=λ/n (2)

W=λ/n (3)

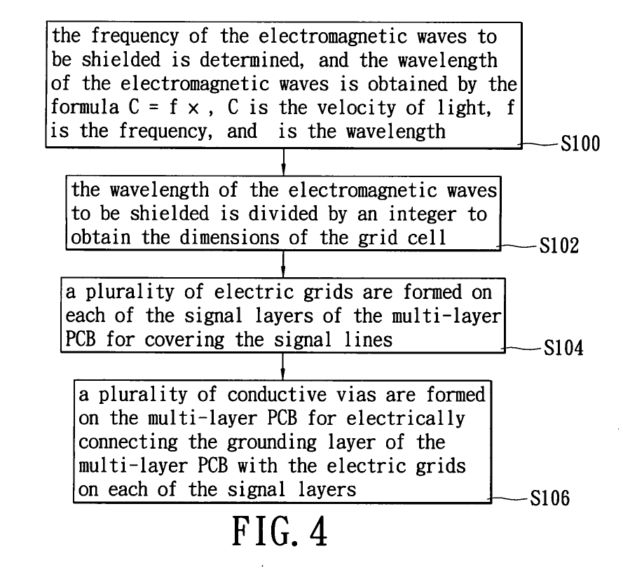

Reference is made to FIGS. 1 and 4. FIG. 4 shows a flow chart of the PCB layout method for suppressing EMI of the present invention. The PCB layout method for suppressing EMI is implemented on a multi-layer PCB 1 with a first signal layer 10, a second signal layer 14 and a grounding layer 12. The method includes the following steps. Firstly, the frequency f of the electromagnetic waves to be shielded is determined, and the wavelength λ of the electromagnetic waves is obtained by the formula C=f×λ, C is the velocity of light (S100). Next, the wavelength λ of the electromagnetic waves to be shielded is divided n (n is an integer) to obtain the length L and the width W of grid cell (S102). A plurality of electric grids 102 are formed on the first signal layer 10 and the second signal layer 14 of the PCB 1, and the electric grids 102 cover the signal lines on the first signal layer 10 and the second signal layer 14 (S104). Next, a plurality of conductive vias 104 are formed on the multi-layer PCB 1, and the conductive vias 104 pass through the first signal layer 10, the second signal layer 14 and the grounding layer 12 to connect the grounding layer 12 with the electric grids 102 on first signal layer 10 and the second signal layer 14 (S106) to form an enclosed grounding net. Thereby, electromagnetic waves of a specific wavelength are shielded by appropriately choosing the dimensions of the electric grids.

The PCB layout structure for suppressing EMI and a method thereof of the present invention use the electric grid layout to shield electromagnetic waves with a specific frequency. The layout structure and method of the present invention can reduce the area distributed by the interference magnetic field to weaken the noise radiation to suppress the interference between signals. Furthermore, the density of the conductive vias 104 can be reduced 30˜50% so that the strength of the PCB will not become weak. Moreover, by using the electric grid 102 layout method of the present invention, the electroplate cost is reduced about 25˜30%.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A PCB layout structure for suppressing EMI, comprising:
a multi-layer PCB having a plurality of signal layers and a grounding layer, wherein each of the signal layers is disposed with a plurality of signal lines;
a plurality of electric grids disposed on each of the signal layers and covering the signal lines on each of the signal layers; and
a plurality of conductive vias electrically connecting the grounding layer with the electric grids on each of the signal layers.

2. The PCB layout structure for suppressing EMI as claimed in claim 1, wherein the electric grid is a grid cell.

3. The PCB layout structure for suppressing EMI as claimed in claim 2, wherein the dimension of the grid cell is determined by the formula C=f×λ, whereby C is the velocity of light, f is the frequency of the electromagnetic waves to be shielded, and λ is the wavelength of the electromagnetic waves to be shielded.

4. The PCB layout structure for suppressing EMI as claimed in claim 3, wherein the length of the grid cell is equal to the wavelength λ of the electromagnetic waves to be shielded divided by an integer.

5. The PCB layout structure for suppressing EMI as claimed in claim 1, wherein the conductive vias are disposed around the multi-layer PCB, the distance between the visas being two times the length of a grid cell, thereby forming an enclosed grounding net.

6. A PCB layout method for suppressing EMI, implemented on a multi-layer PCB, wherein the multi-layer PCB has a plurality of signal layers and a grounding layer, the method comprising:
forming a plurality of electric grids on each of the signal layers of the multi-layer PCB, wherein the electric grids cover the signal lines on each of the signal layers; and
forming a plurality of conductive vias between the layers of the multi-layer PCB, wherein the conductive vias electrically connect the grounding layer with the electric grids on each of the signal layers.

7. The PCB layout method for suppressing EMI as claimed in claim 6, wherein the electric grid is a grid cell and the dimension of the grid cell is determined by the frequency of the electromagnetic waves to be shielded.

8. The PCB layout method for suppressing EMI as claimed in claim 7, further comprising the step of determining the frequency of the electromagnetic waves to be shielded and obtaining the wavelength of the electromagnetic waves to be shielded by the formula C=f×λ before the step of forming a plurality of electric grids.

9. The PCB layout method for suppressing EMI as claimed in claim 8, further comprising the step of dividing the wavelength of the electromagnetic waves to be shielded by an integer to obtain the dimension of the grid cell after the step of obtaining the wavelength of the electromagnetic waves to be shielded.

10. The PCB layout method for suppressing EMI as claimed in claim 8, wherein the C is the velocity of light, f is the frequency of the electromagnetic waves to be shielded, and λ is the wavelength of electromagnetic waves to be shielded.

11. The PCB layout method for suppressing EMI as claimed in claim 7, wherein the conductive vias are disposed around the multi-layer PCB, the distance between the visas being two times the length of a grid cell, thereby forming an enclosed grounding net.
